(19) United States
(12) Patent Application Publication
(10) Pub. No.: US 2007/0247195 A1
(43) Pub. Date: Oct. 25, 2007

(54) LOW OUTPUT-TO-OUTPUT SKEW/LOW JITTER STAGGERED OUTPUT BUFFER

(75) Inventors: Prasad Rao Kotra, Bangalore (IN); Sanjeev Dua, Bangalore (IN)

Correspondence Address: MARGER JOHNSON & MCCOLLOM, P.C., 210 SW MORRISON STREET, SUITE 400, PORTLAND, OR, 97204, US

(73) Assignee: Cypress Semiconductor Corporation, San Jose, CA (US)

(21) Appl. No.: 11/690,010

(22) Filed: Mar. 22, 2007

Related U.S. Application Data
(60) Provisional application No. 60/787,910, filed on Mar. 31, 2006.

(51) Int. Cl. H03K 19/00

(52) U.S. Cl. 326/93

(57) ABSTRACT

A system and method for generating multiple current steered output signals at a centralized location and subsequently routing them to their respective output pads is shown and described. The system and method allow designers to variously stagger output pad configurations while maintaining low output-to-output skew and low jitter.

### RELATED APPLICATIONS

This application claims priority from U.S. Provisional Application No. 60/787,910 filed Mar. 31, 2006, which is incorporated herein by reference.

### FIELD OF THE INVENTION

This invention relates generally to output buffering, and more specifically to maintaining low output-to-output skew and low jitter with variously staggered output configurations.

### BACKGROUND OF THE INVENTION

Many systems include a clock signal to synchronize their electrical operations, e.g., by concurrently initiating those operations on clock signal edges. Presently, however, an increasing number of systems require coordinated operations at spatially-separated locations, rendering synchronization with a single clock signal either impractical or impossible. Thus, these systems commonly include one or more clock buffering devices to generate multiple copies of the clock signal from a common reference clock signal for system-wide distribution.

FIG. 1 shows a typical configuration of a clock buffering device 100. Referring to FIG. 1, the clock buffering device 100 generates multiple clock signals 125A-125C from a reference clock signal 105. An input pad 110 receives and provides the reference clock signal 105 to multiple output buffers 120A-120C, where each output buffer 120A-120C generates a corresponding clock signal 125A-125C responsive to the reference clock signal 105. The output buffers 120A-120C include output pads 122A-122C to output the generated clock signals 125A-125C from the clock buffering device 100.

The reference clock signal 105 is commonly voltage-driven, i.e., the clock transitions correspond to voltage-level variations, thus requiring multiple route buffers 130A-130C to buffer the reference clock signal 105 while en-route to the output buffers 120A-120C. Although the addition of route buffers 130A-130C to clock buffering device 100 allows the reference clock signal 105 to be provided to the Output buffers 120A-120C, their addition comes at a cost of increased clock signal routing delay, increased jitter, and increased system size and timing budget. The voltage-driven reference clock signal 105 is also susceptible to increased jitter from cross-talk when routed too close to a core 140 toggling signal of the clock buffering device 100.

To maintain system-wide synchronization, the clock buffering device 100 must generate the clock signals 125A-125C substantially in-phase with each other, or with a low output-to-output skew. This requirement is typically achieved with strategic placement of the output buffers 120A-120C, e.g., so they have proportional reference clock signal routing delays between the input buffer 110 and the output buffers 120A-120C, and/or by employing a balanced clock tree configuration. In certain applications, however, it may not be possible to symmetrically locate the output buffers 120A-120C, thus resulting in the generation of clock signals 125A-125C with excessive output-to-output skew and jitter.

The output buffers 120A-120C further receive a power supply (not shown), where variations in the voltage-level of the power supply alter the time required to generate the clock signals 125A-125C from the reference clock 105. Since routing the power supply to the output buffers 120A-120C causes losses in voltage-level, or IR-drops, each of the spatially-separated output buffers 120A-120C may receive a different power supply voltage-level which in-turn increases the output-to-output skew.

### DESCRIPTION OF THE DRAWINGS

The invention may be best understood by reading the disclosure with reference to the following drawings:

FIG. 1 shows a typical configuration of a clock buffering device.

FIG. 2 illustrates, in block form, an output buffering device useful with embodiments of the present invention.

FIG. 3 illustrates, in block form, embodiments of the buffer unit shown in FIG. 2.

FIG. 4 illustrates, in block form, embodiments of the output buffer shown in FIG. 3.

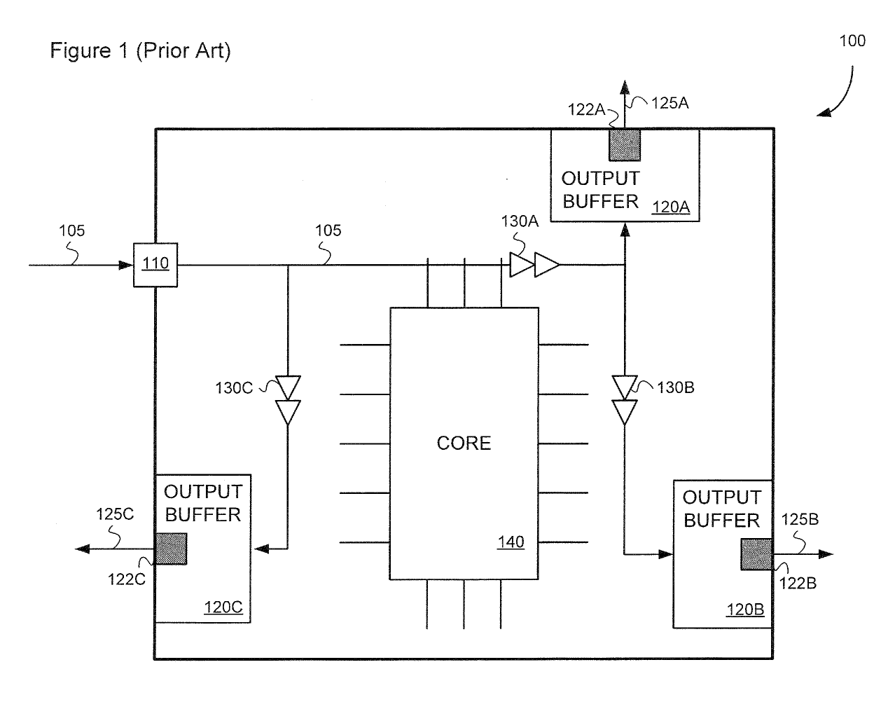

### DETAILED DESCRIPTION

The ability of systems to generate multiple copies of the output signals from a common reference signal with low output-to-output skew and low jitter is advantageous. As described above, prior output buffering devices generate output signals at their spatially-separated output locations, thus requiring strategic design and additional reference signal route buffering to meet skew and jitter requirements. However, by generating multiple output signals at a centralized location and subsequently routing them to their respective output pads, designers gain the freedom to incorporate various output pad configurations into their systems while maintaining low output-to-output skew and jitter. Embodiments of the present invention will now be described in more detail.

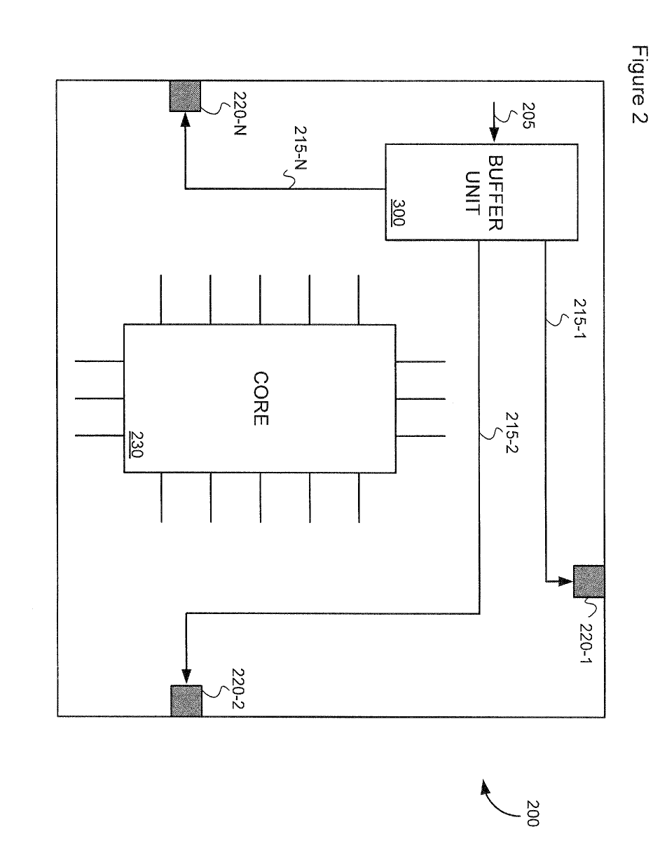

FIG. 2 illustrates, in block form, an output buffering system 200 useful with embodiments of the present invention. Referring to FIG. 2, the output buffering system 200 includes a buffer unit 300 to generate a plurality of output signals 215-1 to 215-N responsive to a reference signal 205. The reference signal 205 may be provided to the buffer unit 300 from any device internal or external to the output buffering system 200, such as an input pad (not shown) or a phase locked-loop device (not shown), The buffer unit 300 provides the output signals 215-1 to 215-N to respective output pads 220-1 to 220-N for transmission from output buffering system 200.

By centralizing the output signal generation, the buffer unit 300 generates the output signals 215-1 to 215-N substantially in-phase, thus reducing output-to-output skew. To minimize the contributions to the output-to-output skew caused by routing the output signals 215-1 to 215-N between the buffer unit 300 and the output pads 220-1 to 220-N, designers may configure output signal routing paths to be substantially equal in length or to have substantially the same capacitance, or preferably both. For instance, tapping one or more of the routing paths, e.g., with capacitance-adjusting stubs, may substantially equalize the capacitance on the output signal routing paths. Thus, by generating the output signals 215-1 to 215-N at a centralized location and routing the output signals 215-1 to 215-N to the output pads 220-1 to 220-N, various output pad 220-1 to 220-N configurations may be realized that maintain low output-to-output skew.

In some embodiments, the buffer unit 300 generates current-driven output signals 215-1 to 215-N, i.e., their signaling is indicated by current-level changes, thus allowing the output signals 215-1 to 215-N to route from the buffer unit 300 to their respective output pads 220-1 to 220-N without requiring additional route buffering. This absence of route buffers along the output signal routing paths increases the throughput of the output buffering system 200, while decreasing jitter and system size. Furthermore, the routing of current-driven output signals 215-1 to 215-N involves lower routing impedance than its voltage-driven counterpart, which corresponds to a reduction of cross-talk with a core 230 toggling signals of the output buffering system 200.

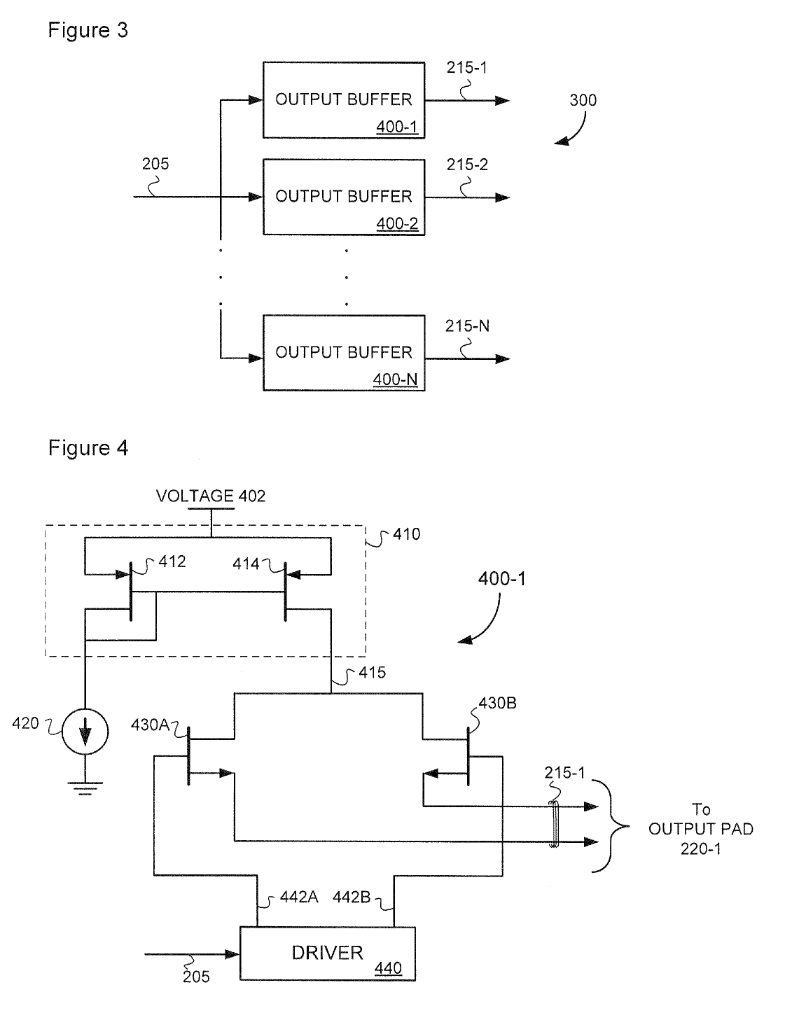

FIG. 3 illustrates, in block form, embodiments of the buffer unit 300 shown in FIG. 2. Referring to FIG. 3, the buffer unit 300 includes a plurality of output buffers 400-1 to 400-N to respectively generate the output signals 215-1 to 215-N from a reference signal 205. In some embodiments, as discussed below in greater detail with reference to FIG. 4, the output buffers 400-1 to 400-N may be current-steered differential circuits for generating complementary output signal pairs.

Each of the output buffers 400-1 to 400-N receives the reference signal 205 at approximately the same phase, thus reducing output-to-output skew caused by output buffers 400-1 to 400-N generating output signals 215-1 to 215-N with minimized phase difference with respect to the reference signal 205. Furthermore, by grouping the output buffers 400-1 to 400-N within the buffer unit 300, each of the output buffers 400-1 to 400-N also receives a power supply of substantially the same voltage-level, as the IR drops associated with routing the power supply to the buffer unit 300 are approximately equal. Thus, potential variations in the voltage-level of the power supply due to IR drops are minimized, allowing the output buffers 400-1 to 400-N to generate the output signals 215-1 to 215-N substantially in-phase.

FIG. 4 illustrates, in block form, embodiments of the output buffer 400-1 shown in FIG. 3. Output buffers 400-2 to 400-N may be configured similarly to output buffer 400-1 shown and described below with reference to FIG. 4. Referring to FIG. 4, the output buffer 400-1 may be configured in a differential current-steered architecture which includes a current mirror 410, a current source 420, a pair of transistors 430A and 430B, and a driver 440. The current mirror 410 is coupled to a supply voltage 402 and a reference current source 420, and generates a reference current 415 that corresponds to the current generated by the reference current source 420. The current mirror 410 includes a master transistor 412 and a slave transistor 414. The slave transistor 414 generates the reference current 415 by mirroring the current passing-through the master transistor 412 as generated by the current source 420. Both of the transistors 412 and 414 receive the supply voltage 402 to facilitate their active operation.

The driver 440 generates drive voltages 442A and 442B responsive to the reference signal 205 and provides them to the gate regions of the transistors 430A and 430B, respectively. The drive voltages 442A and 442B activate transistors 430A and 430B, respectively, when set to a high-level by the driver 440. Once activated, the transistors 430A and 430B steer the reference current 415 generated by the current mirror 410 to an output forming the output signal 215-1. Thus, in the differential circuit embodiments, the output buffer 400-1 generates a complimentary pair of current-driven Output signals 215-1

One of skill in the art will recognize that the concepts taught herein can be tailored to a particular application in many other advantageous ways. In particular, those skilled in the art will recognize that the illustrated embodiments are but one of many alternative implementations that will become apparent upon reading this disclosure.

The preceding embodiments are exemplary. Although the specification may refer to “an”, “one”, “another”, or “some” embodiment(s) in several locations, this does not necessarily mean that each such reference is to the same embodiment(s), or that the feature only applies to a single embodiment.

What is claimed is:

1. A device comprising:
a buffer unit to generate a plurality of output signals at a centralized location responsive to a reference signal, and to route the output signals to a plurality of spatially separated output pads through a corresponding plurality of routing signal paths.

2. The device of claim 1 where the routing signal paths have substantially the same route length.

3. The device of claim 1 where the routing signal paths have substantially the same route capacitance.

4. The device of claim 3 where at least one of the routing signal paths is tapped with a stub configured to adjust the capacitance associated with the routing signal path.

5. The device of claim 1 where the routing signal paths route the output signals to the spatially separated output pads without intermediate route buffering.

6. The device of claim 1 where the buffer unit includes a plurality of centrally located buffers configured to generate the output signals substantially in-phase responsive to the reference signal.

7. The device of claim 6 where the buffers are current-steered differential circuits configured to generate differential pairs of current-driven output signals responsive to the reference signal.

8. The device of claim 1
where the output signals indicate signaling through variations in a current level associated with the output signals; and
where the spatially separated output pads are configured to receive the output signal over corresponding output signal routing paths.

9. A method comprising:
generating a plurality of output current signals at a centralized location according to a reference voltage signal; and
routing the output current signals over separate output routing paths to a corresponding plurality of spatially-separated output pads.

10. The method of claim 9 where the output signal routing paths are substantially equal in length.

11. The method of claim 9 where the output signal routing paths have substantially the same capacitance.

12. The method of claim 11 includes tapping at least one of the output signal routing paths with a stub to adjust the capacitance associated with the tapped output signal routing path.

13. The method of claim 9 includes routing the output signals to the spatially-separated output pads without buffering the signals over the output signal routing paths.

14. The method of claim 9 where the output signals are differential pairs of current-driven output signals.

15. A system comprising:
a first buffer to generate a first output signal responsive to a reference signal;
a second buffer to generate a second output signal responsive to the reference signal, where the first and second output signals are generated substantially in-phase;
a first output pad to receive the first output signal from the first buffer over a first routing signal path; and
a second output pad to receive the second output signal from the second buffer over a second routing signal path, where the first and second output pads are located in spatially separate regions of the system.

16. The system of claim 15 where the first and second routing signal paths have substantially the same route length.

17. The system of claim 15 where the first and second routing signal paths have substantially the same route capacitance.

18. The system of claim 17 where at least one of the first and second routing signal paths is tapped with a stub configured to adjust the capacitance associated with the routing signal path.

19. The system of claim 15 where the first and second routing signal paths route the output signals to the spatially separated output pads without intermediate route buffering.

20. The system of claim 15 where the first and second buffers are current-steered differential circuits configured to generate differential pairs of current-driven output signals responsive to the reference signal.
